(19) United States
(12) Patent Application Publication
(10) Pub. No.: US 2002/0147561 A1
(43) Pub. Date: Oct. 10, 2002

(54) System and method for intelligent wire testing

(76) Inventors: William Baracat, Sterling, VA (US); Mark Brown, Beavercreek, OH (US); Brian Bartlebaugh, Warrenton, VA (US); Lisa Ferrett, Manassas, VA (US); Fonda Fang Liu, Rockville, MD (US)

Correspondence Address: FINNEGAN, HENDERSON, FARABOW, GARRETT &, DUNNER LLP, 1300 I STREET, NW, WASHINGTON, DC, 20005, US

(21) Appl. No.: 09/828,133

(22) Filed: Apr. 9, 2001

(51) Int. Cl. G06F 19/00; G01R 27/28; G01R 31/00; G01R 31/14

(52) U.S. Cl. 702/119

(57) ABSTRACT

A system and method for providing an intelligent wire testing capability for complex hardware systems. The system is comprised of a software application with a relational database interfacing with an automatic test equipment module. The relational database contains all of a system's architecture information plus all of the text and parametric information associated with the design. During a system test, the subject invention uses the wiring/system architecture as disclosed in the relational database together with an automatically generated test program to identify faults in a unit under test. Using the architecture knowledge, the subject invention is capable of automatically generating a wire harness schematic for printout or display on a CRT. The architecture knowledge also allows a technician to quickly distinguish between a broken wire and an unused pin in a connector. After the test, the observed values are stored in a testing results file for later review and trend analysis. Data from the trend analysis provides the technician with the data necessary to assess the state of the wiring in the UUT. At the completion of testing, the testing results file stays with the UUT thereby ensuring access to a complete testing history of the UUT at any time.

### FIELD OF THE INVENTION

The invention relates generally to computer systems and more particularly, to a computer system tool for testing wiring, components and interfaces in a complex system.

### DESCRIPTION OF THE RELATED ART

System engineering is the technical discipline concerned with the conceptualization, design, construction and testing of complex systems. A comprehensive and well-structured approach to system engineering, facilitates the swift, cost-effective progression of new technologies from raw concept to end product.

In the past, system engineering meant that a team of engineers and designers worked together in a labor-intensive, paper laden process throughout the system development life-cycle to conceive and field complex engineering systems. By way of background, the system development life-cycle consists of six stages, the first being concept definition, in which the goals of the project are broadly stated. The output of the concept definition stage become the genesis for the functional design, a high level representation of the major system components and their functional relationships to each other. Once the functional design is completed, the engineers began the task of refining the rudimentary components and interfaces into a detailed design, which may then be used to create a prototype. After the prototype is developed, full-scale production begins, the system is fielded which in turn, leads to the maintenance and field support stages of the process.

While the system development life-cycle has been depicted as consisting of clearly defined, sequential steps, it is well-known that the process of designing complex systems is a recursive process that continues until a favorable system design is produced. In essence, each successive step actually feeds back information to previous steps which are then repeated. It is only after a few iterations of the process that the design stabilizes to eventually yield a finished system that will perform according to specifications.

In most cases, this process is completed manually by technicians and engineers with experience and training in the related field. In the case when computer-aided design (CAD) systems using computers and other information processing devices are used to finalize a system design, it is possible to conduct significantly more tests and analysis while only expending a marginally larger amount of time and financial resources. Even with the benefit of CAD, it is virtually impossible for the technicians and engineers to detect all design defects, configuration control anomalies, and verification omissions that develop during the design process. In the unfortunate event that a system is manufactured according to a design that contains latent design defects, significant economic losses can accumulate from the need to repeatedly update the manufacturing process, such that newly detected design defects are systematically identified and cured. Resolving latent design defects can be further complicated if an accurate configuration control of the system has not been maintained. Since most prior system developments relied on a manual, paperwork-intensive process for maintaining the integrity of system architecture, an accurate configuration control of the system was the exception, not the rule.

Another problem with this manual design process is that verification depends greatly upon the prior experience of the personnel verifying the design. History has shown that there is no easy means of sharing the accumulated experience of one engineer with other engineers, particularly when the knowledge lies in the minds of people located in geographically dispersed areas. As a result, omissions repeatedly occur, with the incidence of errors late in the process particularly high.

Even when CAD systems were used to verify design, the result was usually insufficient, particularly for modern systems. More specifically, prior art CAD systems also tend to simply verify the interoperability with respect to physical properties like component weight, size and dimensions because it is difficult to model and verify the effect of other external influences like temperature, humidity and component age. Prior art CAD systems are also unable to comprehensively verify data obtained through the interaction of components or forces, e.g., the voltage applied to a specific component.

Many of these recognized shortcomings led to the development of automatic test equipment (ATE) to test emerging technologies and verify system design. In the beginning, ATE performed testing of complex microprocessor-based systems through the use of a manually-generated computer program. However, it quickly became obvious that the programs tended to be lengthy, complicated and time-consuming to create. Moreover, the task of writing and supporting testing programs for each of the myriad of ATE platforms was expensive and resource intensive. This in turn led to the development of random instruction generators to produce a random sampling of instructions which were then converted to machine code and executed on a processor or a logical representation of the processor. In related systems known as pseudo random test generators, the developer weights certain instructions or classes of instructions more heavily than others so that the random instructions are biased toward these desired instructions. These systems allow the developer to stress the microprocessor with certain types of instructions observed or believed to cause difficulties. Although random and pseudo-random instruction generators can provide a wide range of possible instruction sequences with minimal user input, they do not intuitively understand which instruction sequences are likely to be the most difficult for the microprocessor to handle. For some designs, such instructions may not test an adequately wide spectrum of instruction sequences. Thus, they fail to adequately test important aspects of a system's functioning and design.

In addition, reports recording the results must describe the verification items, methods, and results, as well as provide the considerations that led to those verification results. Finally, the task of writing such reports must also be streamlined to replace the current time-consuming process.

In view of the shortcomings of currently available system engineering tools, it is desirable to provide a system and method that facilitates the design and development of complex systems. It is also desirable to provide system engineers with a single integrated system and method for storing, describing, and analyzing the physical as well as functional connectivity of a complex system. It is additionally desirable to perform automated electrical testing on such systems, and recording the results of these tests for later historical trending and analysis.

### SUMMARY OF THE INVENTION

The present invention satisfies the above-described need by providing a relational database model of a physical system for supporting a broad spectrum of user functions including design analysis, operations assessments, real-time maintenance and configuration management. One embodiment of the invention provides a single, comprehensive description of the subsystems contained within a complex system, including physical layout, operational constraints, functional requirements, and practical limits.

The organization of information in the complex system model is derived from an object-oriented analysis of the system. In the invention, physical pieces of equipment are represented as objects with attributes that can be verified (primary data) and relations, including connectivity, grouping, and location.

The present invention is a system and method for providing an intelligent wire testing capability for complex hardware systems. The system is comprised of a software application with a relational database interfacing with an automatic test equipment module. The relational database contains all of a system's architecture information plus all of the text and parametric information associated with the design. The subject invention uses the wiring/system architecture as disclosed in the relational database, and can to distinguish a broken wire from an unused pin in a connector, and perform appropriate tests. With the architecture knowledge, an accurate wiring test program can be created and executed, and an assessment of system health can be obtained.

The present invention also provides a machine instruction generator which provides a sequence of processor test instructions by traversing sites on a network. The sequence of processor instructions is generated by selecting a site on a network, randomly or purposely selecting a test sequence available at that site (by virtue of the site's local state) adding that test sequence to an automatic test program, and moving to an adjacent site. The system generates an inherently wider spectrum of test sequences than the prior art random and pseudo-random generators. When the test program produced from a network is complete, it is concurrently tested on a functional model of the system and a logical design of the system. Any discrepancy in the results of these two tests indicates that an anomalous condition has been found in the system.

The present invention further provides the capability to automatically generate test programs in response to basic user inputs. More specifically, the present invention provides the capability to generate test programs from user-specified test parameters and thresholds.

It is to be understood that both the foregoing general description and the following detailed description are exemplary and explanatory and are intended to provide further explanation of the invention as claimed.

Additional features and advantages of the invention will be set forth in the description which follows, and in part will be apparent from the description, or may be learned by practice of the invention. The objectives and other advantages of the invention will be realized and attained by the methods, systems, and apparatus particularly pointed out in the written description and claims hereof, as well as the accompanying drawings.

### BRIEF DESCRIPTION OF THE DRAWINGS

In the drawings:

FIG. 1 is a diagram illustrating the Automated System Quality Assurance (ASQA) network in accordance with the present system;

FIG. 2 is a diagram illustrating an automatic test equipment (ATE) controller in accordance with the present invention;

FIG. 3 is a flow diagram depicting the operation of ATE controller during conduct of a test;

FIG. 4 is a detailed flow diagram depicting the operation of ATE controller during the conduct of a test;

FIG. 5 is a Test Setup Screen in accordance with the present invention;

FIG. 6 is a View Results Screen in accordance with the present invention;

FIG. 7 is a Display Failures Screen in accordance with the present invention;

FIG. 8 is a graphical schematic drawing in accordance with the present invention;

FIG. 9 is a Self-Learn Screen in accordance with the present invention;

FIG. 10 is a Result File Archive Screen in accordance with the present invention;

FIG. 11 is a Interface Module display Screen in accordance with the present invention;

FIG. 12 is a Continuity Test Screen in accordance with the present invention;

FIG. 13 is a Insulation Test Screen in accordance with the present invention;

FIG. 14 is a Isolation Test Screen in accordance with the present invention;

FIG. 15 is a DC HiPot Test Screen in accordance with the present invention;

FIG. 16 is an AC HiPot Test Screen in accordance with the present invention; and

FIG. 17 is a Capacitance Test Screen; and in accordance with the present invention.

### DETAILED DESCRIPTION OF A PREFERRED EMBODIMENT

In the following detailed description of one embodiment, reference is made to the accompanying drawings that form a part thereof, and in which is shown by way of illustration a specific embodiment in which the invention may be practiced. This embodiment is described in sufficient detail to enable those skilled in the art to practice the invention and it is to be understood that other embodiments may be utilized and that structural changes may be made without departing from the scope of the present invention. The following detailed description is, therefore, not to be taken in a limited sense.

To achieve these and other advantages, and in accordance with the purpose of the invention as embodied and broadly described, the invention provides an object-oriented database model of a physical system for supporting a broad spectrum of user functions including design analysis, operations assessments, real-time maintenance and configuration management. One embodiment of the invention provides a single, comprehensive description of the modules and subsystems contained in a complex system, including physical layout, operational constraints, functional requirements, and practical limits.

The organization of information in the complex system model is derived from an object-oriented analysis of the system. In the invention, physical pieces of equipment are represented as objects with attributes that can be verified (primary data) and relations, including connectivity, grouping, and location.

The present invention provides a machine instruction generator which creates a sequence of processor test instructions by traversing sites on a network. The sequence of processor instructions is generated by selecting a site on a network, randomly or purposely selecting a test sequence available at that site (by virtue of the site's local state) adding that test sequence to an automatic test program, and moving to an adjacent site. The system generates an inherently wider spectrum of test sequences than the prior art random and pseudo-random generators. When the test program produced from a network is complete, it is concurrently tested on a functional model of the system and a logical design of the system. Any discrepancy in the results of these two tests indicates that an anomalous condition has been found in the system.

Turning first to the nomenclature of the specification, the detailed description which follows is represented largely in terms of processes and symbolic representations of operations performed by conventional computer components, including a central processing unit (CPU), memory storage devices for the CPU, and connected pixel-oriented display devices. These operations include the manipulation of data bits by the CPU and the maintenance of these bits within data structures residing in one or more of the memory storage devices. Such data structures impose a physical organization upon the collection of data bits stored within computer memory and represent specific electrical or magnetic elements. These symbolic representations are the means used by those skilled in the art of computer programming and computer construction to most effectively convey teachings and discoveries to others skilled in the art.

For the purposes of this discussion, a process is generally conceived to be a sequence of computer-executed steps leading to a desired result. These steps generally require logical manipulations of physical quantities. Usually, though not necessarily, these quantities take the form of electrical, magnetic, or optical signals capable of being stored, transferred, combined, compared, or otherwise manipulated. It is conventional for those skilled in the art to refer to these signals as bits, values, elements, symbols, characters, terms, objects, numbers, records, files or the like. It should be kept in mind, however, that these and similar terms should be associated with appropriate physical quantities for computer operations, and that these terms are merely conventional labels applied to physical quantities that exist within and during operation of the computer.

It should also be understood that manipulations within the computer are often referred to in terms such as adding, comparing, moving, etc. which are often associated with manual operations performed by a human operator. It must be understood that no such involvement of a human operator is necessary or even desirable in the present invention. The operations described herein are machine operations performed in conjunction with a human operator or user who interacts with the computer. The machines used for performing the operation of the present invention include general purpose digital computers or other similar computing devices.

In addition, it should be understood that the programs, processes, methods, etc. described herein are not related or limited to any particular computer or apparatus. Rather, various types of general purpose machines may be used with programs constructed in accordance with the teachings described herein. Similarly, it may prove advantageous to construct specialized apparatus to perform the method steps described herein by way of dedicated computer systems with hard-wired logic or programs stored in nonvolatile memory, such as read only memory.

The operating environment in which the present invention is used encompasses general distributed computing systems wherein general purpose computers, workstations, or personal computers are connected via communication links of various types. In a client server arrangement, programs and data, many in the form of objects, are made available by various members of the system. Primary data for an object are input directly by a user. The use of windowing in the user interface permits precise control of input data at the point of entry using pull down menus and slider bars having a range bounded by the physical limits of the modeled equipment. Thus, out of range or incorrect settings are not possible and a user can be guided through an interactive data input process with little previous experience or training.

While the user of the invention is typically an engineer having responsibility for maintaining configuration control of the engineering design, it is important to note that the user interface also allows efficient data entry by administrative personnel. Thus, the present invention features a consistent graphical user interface across all applications and for all users. A user enters attribute data via pop-up menus, pull-down menus, scrollable lists, enterable fields, dialog boxes, and mouse pointing device support, generic implementation of which is well known in the art. The invention allows several editors to be active at the same time. An editor can be started for any object in the database by clicking on any reference to that object. In the equipment editor windows, the user selects from option lists that only offer valid choices. Existing equipment may be used as a template to simplify data entry for new equipment.

A system in accordance with the present invention, provides a database that finds application, for example, in the design and integration of complex electromechanical and software systems. The invention provides the user with a single integrated source for storing, describing, and analyzing the physical as well as functional connectivity of a complex system (i.e., data communications, power, thermal, etc.) The present system models functional entities (components) and the connectivity (paths) between functional entities. Components and path data files are used to capture the system architecture as a function of time and define the physical and functional connectivity. A preferred embodiment of the present invention includes files containing supporting information such as system, location, description, function, types, and engineering parametric data. A second set of files support implementation of the analysis and assessment applications.

The present invention is also structured to allow integrated schematics to be generated from any component or path in real time. These schematics can then be stored for later modification, display and printing.

Referring now to the drawings, in which like numerals represent like elements throughout the several figures, the present invention will be described.

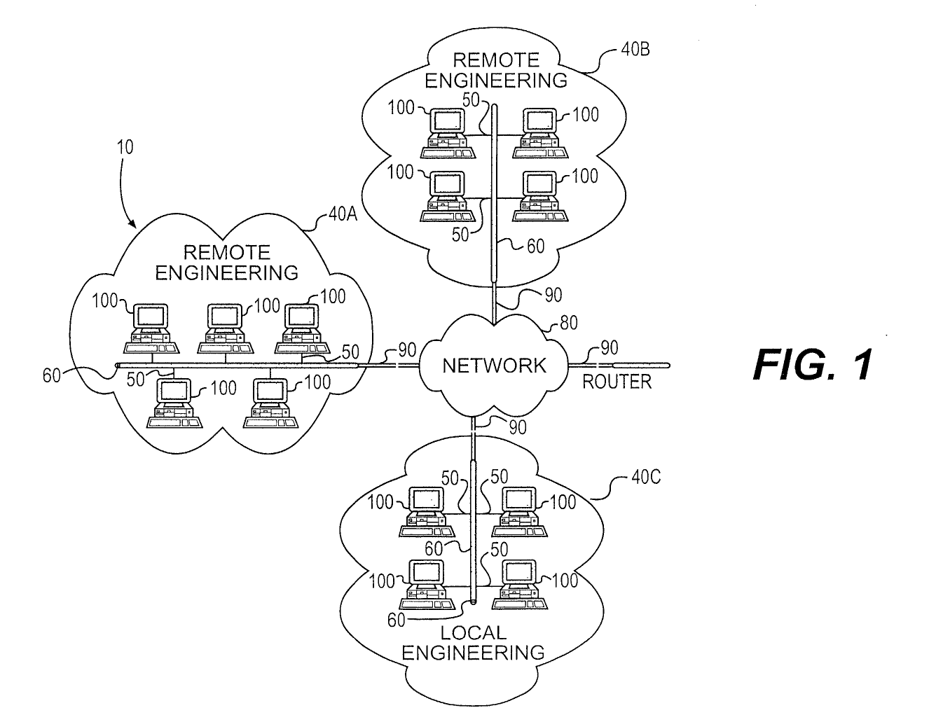

An Automated System Quality Assurance (ASQA) network system 10, shown in FIG. 1, is comprised of a plurality of subnetworks 40a-c located in diverse locations over a wide geographic area with associated automatic test equipment (ATE) controllers 100. Each subnetwork 40 is more specifically comprised of a plurality of interconnected computers and microprocessors hosting a plurality of operating systems. By way of example, subnetwork 40 can be comprised of pentium™ based microprocessors operating on Windows 95, 98, NT or 2000 operating systems. Each subnetwork 40 is correspondingly coupled to a larger network 80 via a plurality of routers 90 that connect the subnetwork backbone 60 to network 80. ATE controllers 100 are in turn connected to sub-network backbone 60 via a series of network interface cables 50. While this figure depicts three separate sub-networks, it is understood by those of skill in the art that the number of sub-networks is only limited by the size and complexity of ASQA network 10.

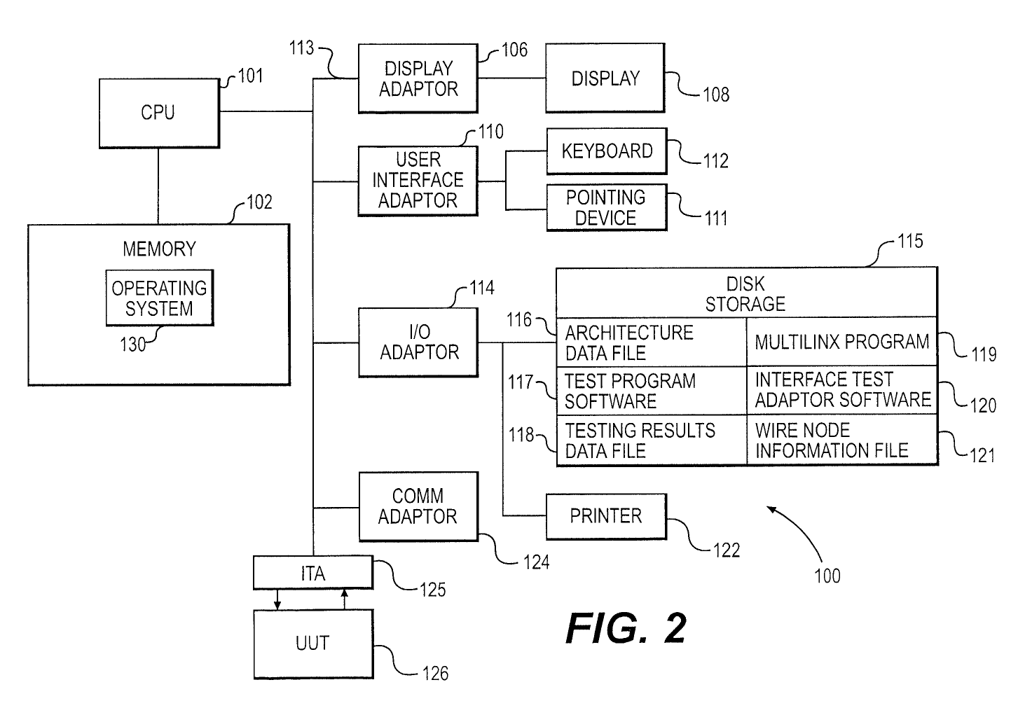

A detailed diagram of ATE controller 100 is shown in FIG. 2. As shown, ATE controller 100 is comprised of a central processor unit (CPU) 101, a memory 102, a display adapter 106, a display 108, a user interface (UI) adapter 110, a pointing device 111, a keyboard 112, an input/output (10) adapter 114, a disk storage unit 115, and a communications adapter 124 for providing a communications function to network 80.

The various components of ATE controller 100 communicate through a system bus 113 or similar architecture. As further shown in FIG. 2, display adaptor 106 is coupled to display 108, user interface adaptor 110 is coupled to pointing device 111 and keyboard 112, I/O adaptor 114 is coupled to disk storage unit 115 and printer 122. Communications adaptor 124 is coupled to network interface cable 50 (shown in FIG. 1) for providing connectivity between ATE controller 100 and network 80. Adaptor 124 permits a user at a first ATE controller 100 to access memory associated with another ATE controller 100 and to send commands to other ATE controllers. Also shown in FIG. 2 is an Interface Test Adaptor (ITA) 125 and a unit under test (UUT) 126. ITA 125 is a hardware interface that allows ATE controller 100 to connect to UUT 126. ITA 125 is comprised of a plurality of data ports and connectors that couple to corresponding UUT connections (not shown). The connections between ITA 125 and UUT 126 allow ATE controller 100 to send signals to, and receive signals from UUT 126.

Memory 102 as further shown in FIG. 2, includes an operating system 130 for 15 operating the device. The operating system 130 controls and coordinates running of the ATE controller 100 in response to commands issued by a user via user interface adaptor 110 or received by communications adaptor 124 via the network interface cable 50 from users of other ATE controllers on ASQA network 10.

Disk storage 115 includes an architecture data file 116, test program software 117, 20 testing results data file 118, Multilinx program 119, interface test adaptor software 120, and wire node information file 121. Architecture data file 116 is a database that finds application, for example, in large-scale engineering system design, development, manufacturing, testing and operational support. The data model of the present invention defines and maintains functional entities (components) and the connectivity between these entities (paths). At a minimum, architecture data file 116 is comprised of historical design data gathered during the design of a particular UUT. During the design and development of a complex system, a test engineer will review the work and the functional tests performed on the system. After reviewing the work performed on the system, the test engineer accesses architecture data file 116 and reviews its contents against the tests performed. If the review indicates that certain required functional tests have not been performed on the system, or that those tests indicate that the tested components failed functional testing, the test engineer will take appropriate remedial action to ensure that all components are fully tested and the results accurately recorded in the architecture data file 116. Architecture data file 116 may also contain historical performance data for a particular UUT. The historical performance data may be recorded from a specific UUT or a class of UUTs. For example, architecture data file 116 can record performance data observed by the ATE controller 100 from a UUT or a class of UUTs coupled to the ATE controller. Architecture data file 116 can also record performance data observed by other ATE controllers 100 coupled to ASQA network 10. For example, an ATE controller 100 associated with subnetwork 40a in one location can access one or more ATE controllers associated with subnetworks 40a. It can also access one or more ATE controllers associated with subnetworks 40b and 40c in other locations. In one embodiment of the invention, architecture data file 116 is maintained in a single database using a window-based graphical user interface.

Test program software (TPS) 117 interfaces with the ITA 125 to test UUT 126. TPS 117 contains the instructions that direct ITA 125 to exercise UUT 126 and record its responses.

Testing results data file 118 is used to collect and organize all the test results. At periodic intervals during the lifetime of the system, a completed test results record will be added to the testing results data file 118 to ensure a complete and periodic record of the assembly, maintenance, and functional testing of the system. In another embodiment, the testing results data file 118 is separate from the other portions of disk storage 115 and is typically a write-only type of memory, such as an optical disk. The system assembly, manufacture, and maintenance records are then always available for review as may be required.

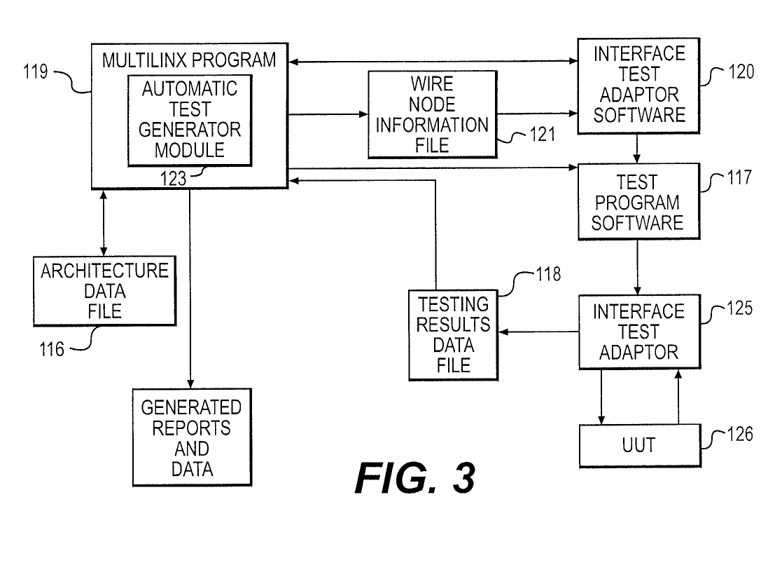

Multilinx program 119 interfaces with architecture data file 116 during a particular test to compare expected values or ranges to observed values for a plurality of UUT terminals. This comparison is used to determine whether a UUT passes or fails. Multilinx program 119, (as shown in FIG. 3), is further comprised of an automatic test generator (ATG) module 123 that provides the capability for Multilinx program 119 to automatically create test programs that may be loaded into ITA 125 and executed. ITA software 120 contains proprietary data and UUT-unique information that will allow information, commands, and data to flow from the UUT 126 to CPU 101. ITA software 120 is loaded into ITA 125 before a test is initiated.

Wire node information file 121 contains historical wire node information that may be compared to observed data to assess the condition of a wire or other connector. It is important to keep in mind that the components shown in FIG. 2 are illustrative of a typical ATE controller 100. ATE controller 100 may be comprised of other components as well, but these are not shown to facilitate description of the unique aspects of this embodiment of the invention. The hardware and software arrangement of this computer, as well as the other computers discussed in this specification is intentionally shown as general, and is meant to represent a broad variety of architectures, which depend on the particular computing device used.

With this basic understanding of the ASQA Network 10, ATE controller 100 and architecture data file 116, the ASQA will now be explained in greater detail by initial reference to FIG. 3, which illustrates the data communication process during a typical system test. ATE controller 100 is designed to simulate and monitor signals generated by UUT 126. Stimuli from database ATE controller 100 and measurements taken therefrom are used to functionally test components and subsystems of the UUT 126. Tests performed by ATE controller 100 include: verifying the integrity of the UUT's wiring; testing the functionality of UUT circuits; and, testing systems that report UUT 126 state information.

During a system test, ITA software 120 commands ITA 125 in response to signals received from ATE controller 100. ATE controller 100 controls ITA 125 by means of signals produced by the ATE controller 100 on bus 113. Operating system 130 as shown in FIG. 2 can, upon request, load and execute TPS 117. When the TPS is running, the program causes signals to be issued on bus 113 that are received by UUT 126 via the ITA adaptor. The test results, in the form of digitized values of voltages or other parameters, are then returned to the ATE controller 100. During a test, input signals are applied to each UUT connection via ITA 125. Output signals from UUT 126 are correspondingly measured and observed by ATE controller 100 via ITA 125.

In operation, a user logs on to ATE controller 100 via keyboard 112 (FIG. 2) and inputs a command to start a system test which causes the MP 119 to be loaded into memory from disk storage 115, and executed. The MP 119 produces an appropriate start test command at I/O adaptor 114 that is received by ATE controller 100 via bus 113 . It will be understood by those skilled in the art that references herein to a program taking an action are simply a shorthand way of stating that the associated data processor takes the specified action under the control of the specified program. In response to the start test signal, the ATE controller 100 loads ITA software 120 and test program software 117 from disk 115. ATE controller 100 also loads MP 119 that in turn commands CPU 101 to load architecture data file 116. ATE controller 100 then executes the test. During the test, ITA software 120 interacts with TPS 117 and ITA hardware 125 to test UUT 126. The results produced by the test are transmitted back to ATE controller 100 via bus 113. MP 119 receives the test results and transmits all test results to printer 122, and to testing results data file 118. When the test is complete, an appropriate test-completed signal is transmitted to ATE controller 100 and the process terminates. If no failures have been detected, the MP 119 sends appropriate messages to testing results data file 118 and printer 122 indicating that the functional test has been successfully completed. However, if a test resulted in a failure, MP 119 would attempt to determine the cause of the failure. More specifically, MP 119 reads wire node information file 121 on disk storage 115 and compares the observed data values to values stored in wire node information file 121 to determine whether the source of the failure is a component failure or a path (wire) failure. Once a final determination is made as to the source of the fault, the program completes.

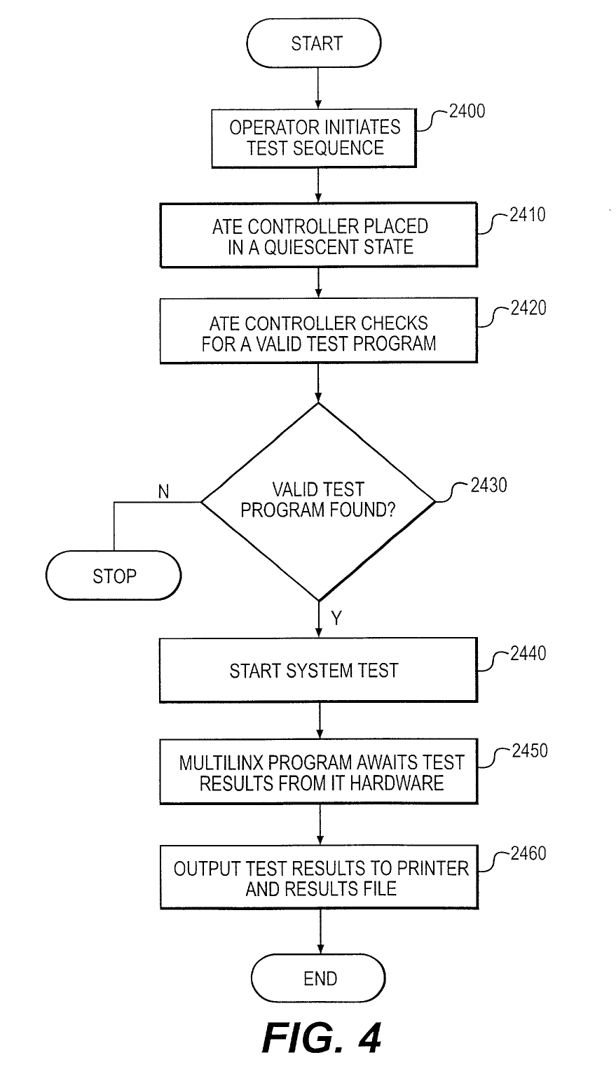

In general, a system test comprises a series of discrete tests. In each test, input signals are applied to a first set of UUT terminals. The resulting output signals at a second set of UUT terminals are measured, and the values digitized and stored. The output signal values are then compared to expected values or ranges, and a determination of pass or fail is made. A representative example of the operation of ATE controller 100, during the conduct of a test, is set forth in FIG. 4. A test sequence is initiated in block 2400 by an operator activating a predetermined key or key sequence on keyboard 112. Activation of the key causes the MP 119 to be loaded and run. In block 2410, the MP 119 sends a message to CPU 101 that puts the ATE controller 100 in a quiescent state in which the ATE controller is not conducting any tests but is ready to receive commands. In block 2420, the MP 119 causes the ATE controller 100 to check disk storage 115 for the existence of a valid test program 117 and ITA software program 120, given the identification of the UUT. If a valid file is found (step 2430), this fact is transmitted back to MP 119 which then issues a command to the ATE controller 100 to start the system test (block 2440). The ATE controller 100 receives the start command and commences execution of the system test. The system test may begin by requesting certain information, such as operator name, data, etc. If a valid test file is not found, processing terminates. As each test is completed, the results of that test are transmitted back to ATE controller 100 over bus 113. In block 2450, MP 119 awaits test results from the ITA hardware 125 via testing results data file 118. For each test result received, MP 119 determines whether the results indicate a component failure or a deterioration of a path (wire) connected to a component. The nature of an observed failure is conclusively determined by extracting the observed signal, comparing it to expected values and signal trends as stored in wiring node information file 121. Upon completion of the system test, MP 119 outputs test results to the printer and to the testing results data file (step 2460).

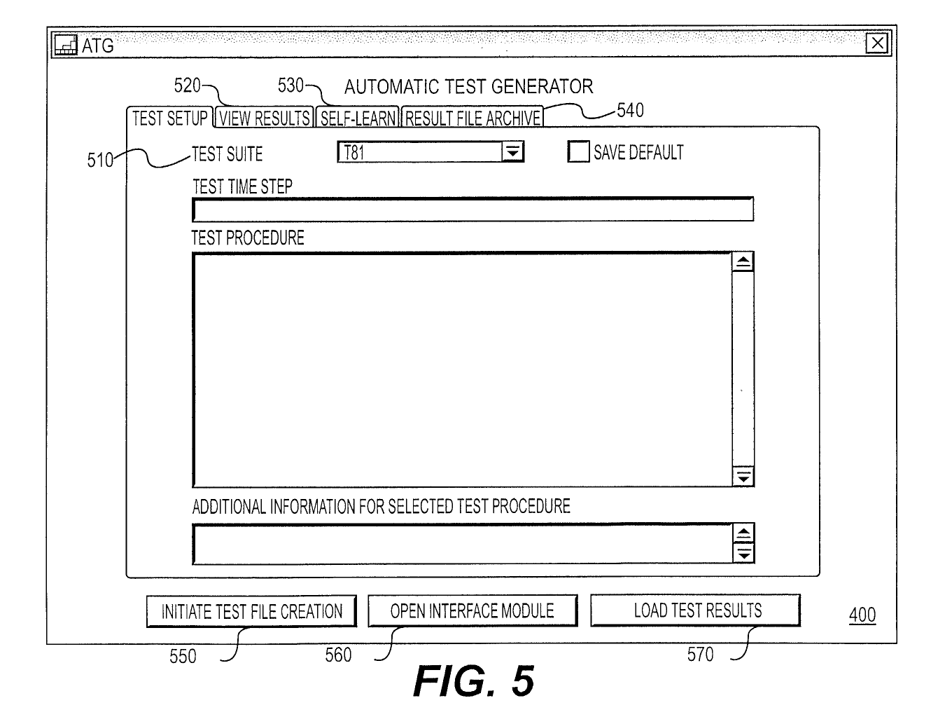

Prior to a system test, test program software 117 must be created. Test program software 117 may be generated by randomly selecting testing results data files 118 for similar systems across ASQA Network 10, evaluating these files and producing a valid sequence of instructions that reflects a comprehensive test program for a particular system. Alternatively, ATG module 123 may create test programs based on information inputted by a user and information stored in Multilinx Program 119. In one embodiment, information is inputted into ATG module 123 via a user interface shown generally in FIG. 5. As shown in FIG. 5, Test Setup Screen 500 is comprised of four drop down menus and three buttons. The drop down menus are entitled: Test Setup tab 510, View Results tab 520, Self-Learn tab 530 and Result File Archive tab 540. Clicking on a tab will reveal a display to the user that elicits information necessary to select and execute a system test. As shown in FIG. 5, Test Setup tab 510 is further comprised of four inputs: Test Suite, Test Time Step, Test Procedure, and Additional Information. These inputs allow a user to specify a test executive, a time step and a test procedure. The three buttons shown in FIG. 5 are labeled: “Initiate Test File Creation” button 550, “Open Interface Module” button 560, and “Load Test Results” button 570. Clicking on the “Initiate Test File” button 550 causes the Multilinx Program 119 to access the Architecture Data File 116 for the UUT 126 and determine the component connectivity of the UUT 126 as modeled in file 116. Clicking on the “Open Interface Module” button 560 allows a user to run a previously created test program or to create a new test program based on the previous wire node information file 121. Clicking on the “Load Test Results” button 570 causes Multilinx Program 119 to access testing results data file 118 and load a historical test results file.

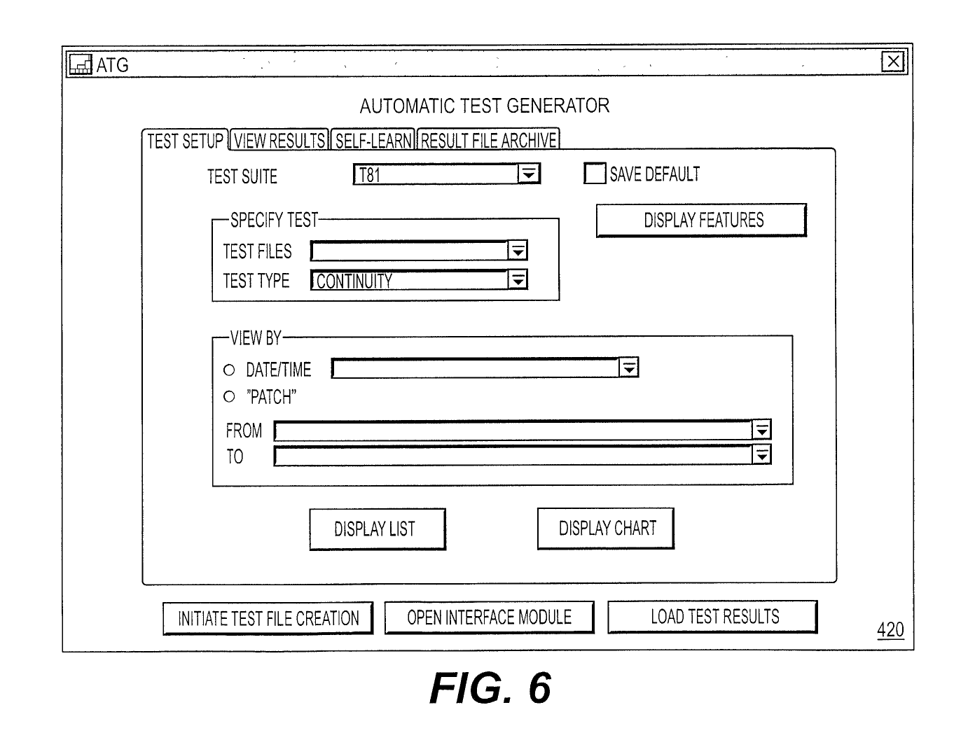

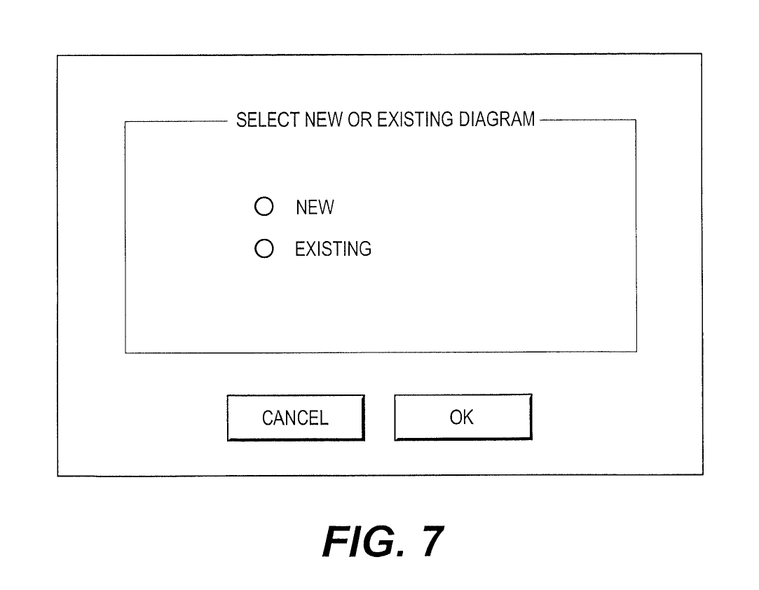

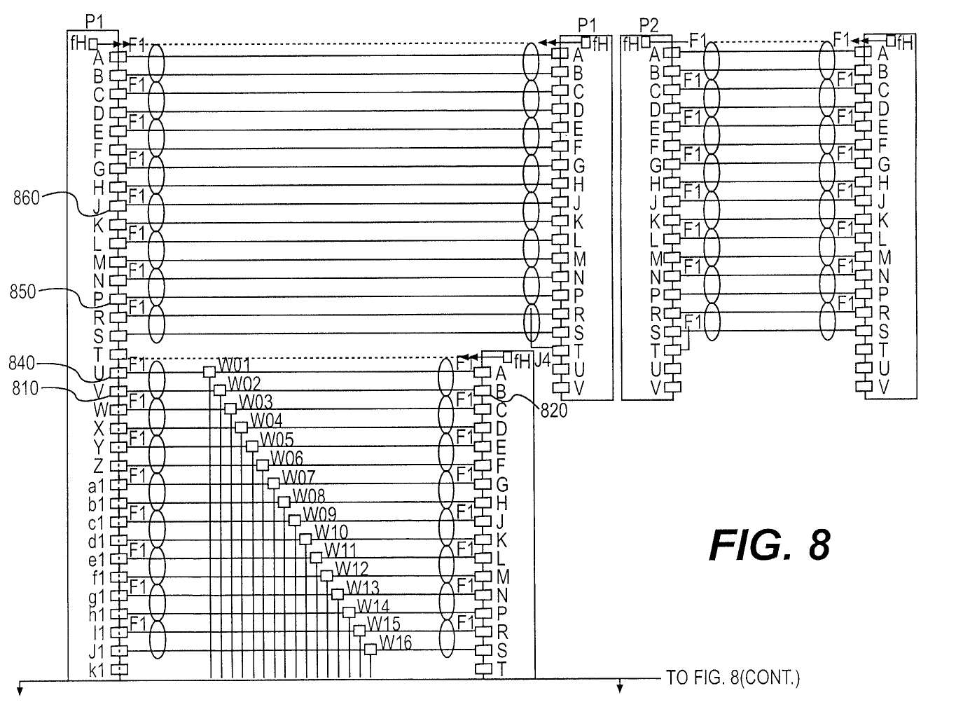

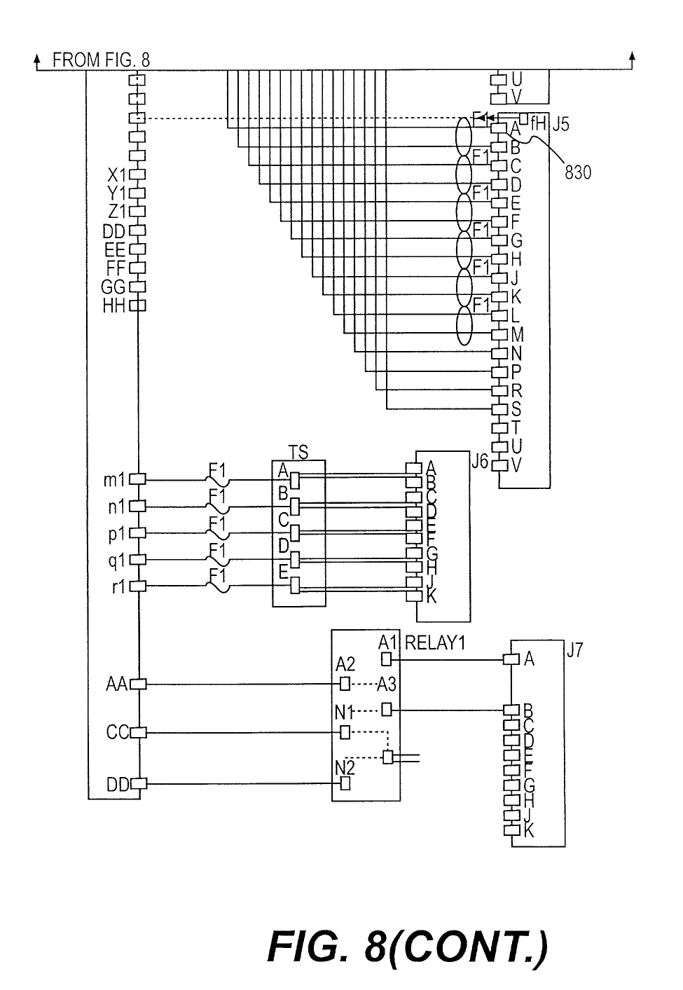

Clicking on the View Results tab 520, reveals a display shown in FIG. 6. As shown, View Results tab 520, allows the user to view the resulting output from a test, according to user-specified parameters. View Results tab 520, as further shown in FIG. 6, is comprised of three input areas: Test Suite, Specify Test, and View By. These inputs allow a user to specify a test executive, specify the test program that was used to produce the testing results data file 118, specify the type of results viewed, and specify how they would like the results viewed. The three buttons shown on the View Results tab 520 are: Display Failures, Display List and Display Chart. These buttons allow the user to display the failures, display the test results in a list format, and display a specific range of test results, respectively. When a user selects Display Failures, a screen similar to FIG. 7 is shown on the user's computer. If an existing diagram is selected, the failures will appear on the selected diagram. As shown in FIG. 8, failures are shown as ovals (labeled 810-860).

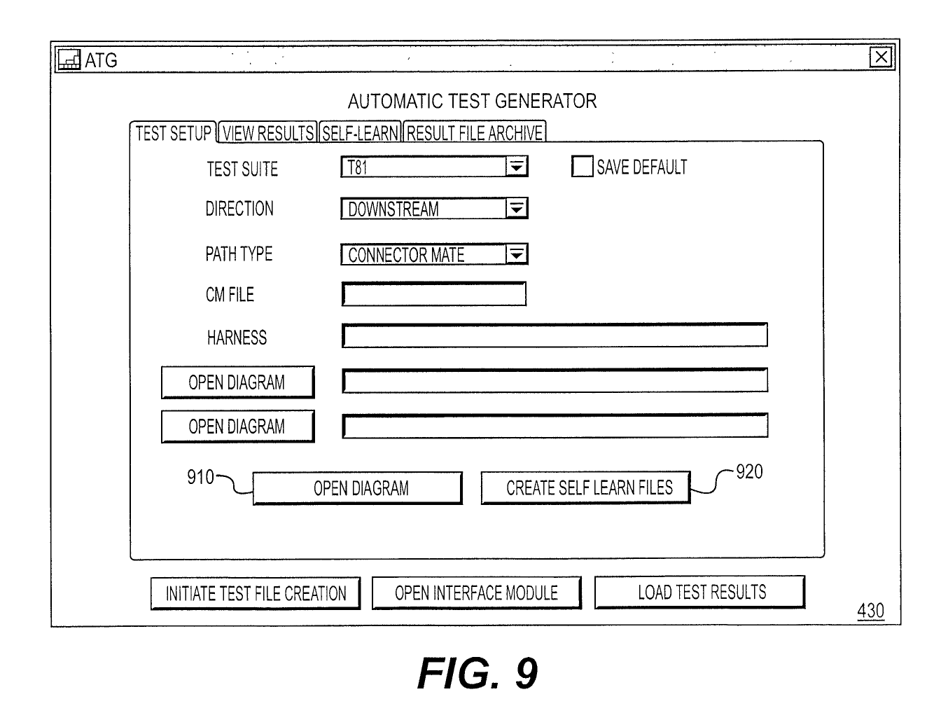

Clicking on the Self-Learn tab 530, reveals a display shown in FIG. 9. The Self-Learn tab 530, allows a user to access “self-learn” or “autoprogramming” features of a test executive. The self-learn feature allows the software to learn and automatically generate a diagram similar to that shown in FIG. 8. As shown in FIG. 9, the Self-Learn tab 530 is comprised of seven data input areas: Test Suite, Direction, Path Type, CM File, Harness, Select TAC File, and Read Self-Learn File. These input areas allow the user to select the direction of a set of wires to be learned (upstream/downstream), the path type, the CM file, the harness, the TAC file, and the Self-Learn file, respectively. The two buttons shown in the Self-Learn tab 530 are: Open Diagram button 810 and Create Self Learn File button 820. Open Diagram button 810 allows the user to open a previously created diagram file and Create Self-Learn file button 820 allows the user to create a self-learn file.

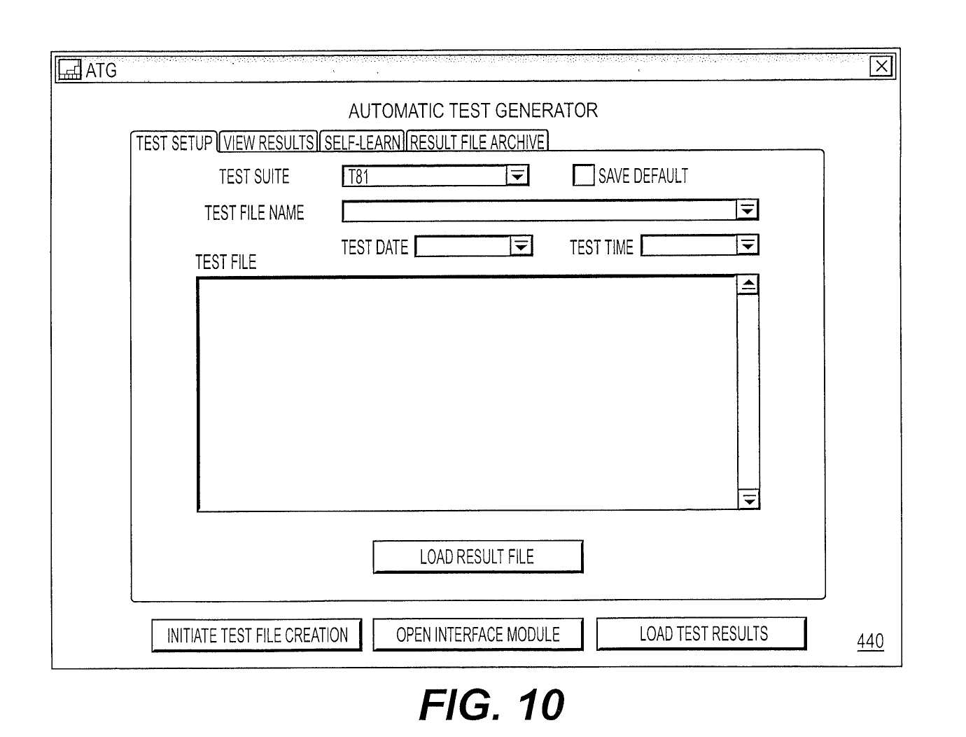

Clicking on the Result File Archive tab 540, reveals the display shown in FIG. 10. The Result File Archive tab 540 allows the user to perform “bulk” storage and archiving of an entire testing results data file 118. As shown in FIG. 10, the Result File Archive tab 540 is comprised of five input areas: Test Suite, Test File Name, Test Date, Test Time, and Test File. These input areas allow the user to select the test file which created the test program, select the test date and time for the archived data, and display the archived data, respectively. The Load Result File button shown in the Result File Archive tab 540, allows a user to select an error log file to be archived.

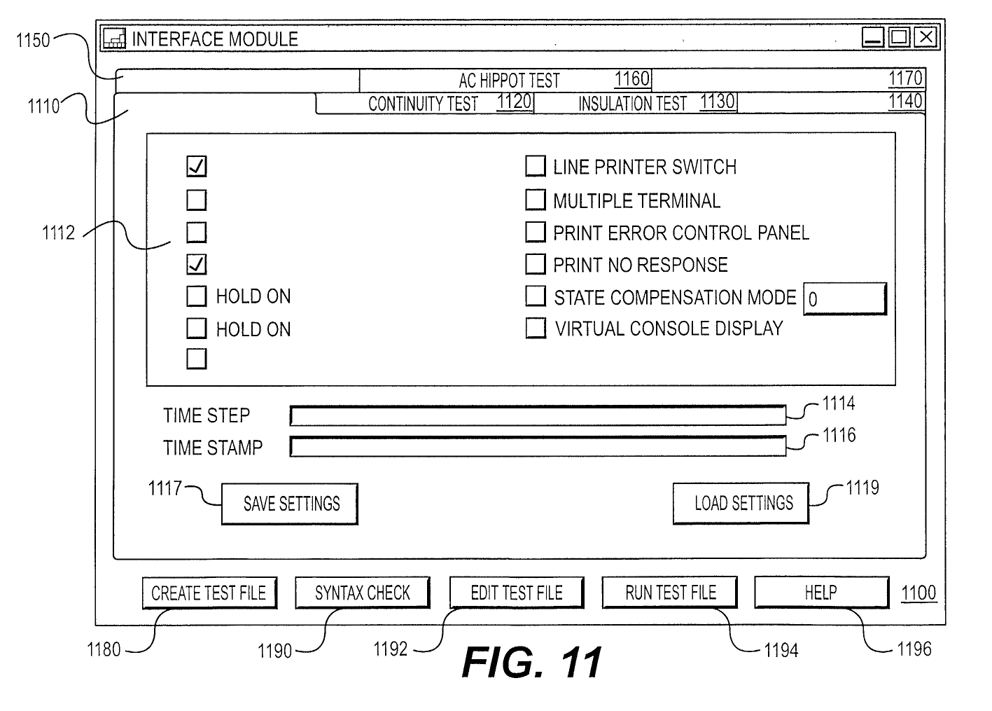

Once information is inputted into ATG Module 123, processing flows to the ITA software 120 where the user is given an opportunity to select the test mode as well as how and where to display the results. In one embodiment, the user is provided with an Interface Module display screen 1100, similar to that shown in FIG. 11. As shown, Interface Module display screen 1100 is comprised of seven tabs and five buttons. More specifically, in one embodiment, Interface Module display screen 1100 is comprised of: a Test Mode tab 1110, a Continuity Test tab 1120, an Insulation Test tab 1130, an Isolation Test tab 1140, a DC HiPot Test tab 1150, an AC HiPot Test tab 1160, and a Capacitance Test tab 1170. Interface Module display screen 1100 is also comprised of: a Create Test File button 1180, a Syntax Check button 1190, an Edit Test File button 1192, a Run Test File button 1194, and a Help button 1196. The test mode tab 1110, as shown in FIG. 11 is comprised of a plurality of test modes 1112a-m, two inputs: Time Step 1114 and Time Stamp 1116, and two buttons: Save Settings 1117 and Load Settings 1119. Referring now to the test modes 1112, it is shown that the Continuity Error Scan Both mode 1112a tests both the output and input test points for inappropriate connections. The Continuity Error Scan mode 1112b allows the system to determine if the failed output test point in a continuity test connects to a string to which it should not. The Certified Test Message mode 1112c will add “Non Certified” to error log 118 when the system has detected the errors and add “Certified” to error log 118 when the system has not detected any errors. The Dwell Time Bypass mode 1112d allows the system to go to the next test as soon as a PASS condition is reached, without waiting until the maximum dwell time has elapsed. The Hold on Test mode 1112e causes the system to apply stimulus until the user advances the test program. In one embodiment, the user can terminate the test by striking the “,”, “ESC” or “/” key during execution. The Hold on Fail mode 1112f causes the system to apply stimulus until a FAIL condition is reached. These modes are usually used for troubleshooting and maintenance. The Kelvin option 1112g can be used to set up the switching system logic for Kelvin (four wire) testing. The Line Printer Switch mode 1112h permits the user to allow/prevent the system from printing the error log. The Multiple Terminal Test mode 1112i allows user to set up the four Multiple Terminal Test jacks for bulk testing. The Print Error at Control Panel Device option 1112j allows user to monitor testing from test station 100. The Print “No” Response mode 1112k allows the user to count numbers when “NO” has been entered in response to “Control Panel Response”. The Tare Compensation mode 1112l allows for temporary balancing (tare) of the resistance of test adapter cables. The Virtual Console Display mode 1112m will display the input and output addresses on the system console. The Time Stamp output window displays the time when system began test file creation. The Load/Save Settings buttons 1119 and 1117, respectively, allow the user to save or load any configuration of settings.

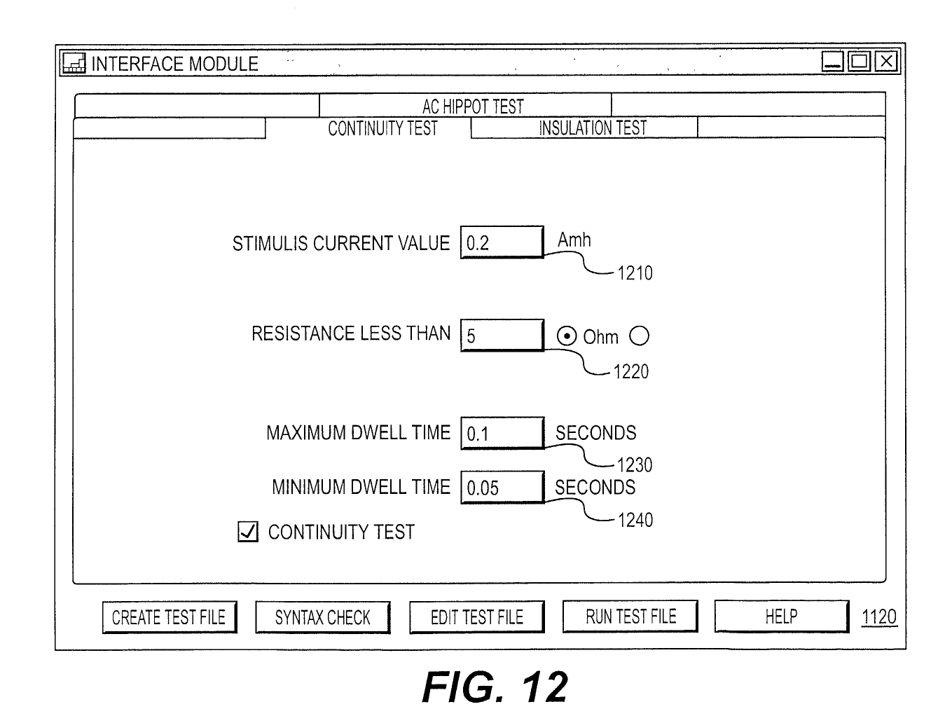

Clicking on the Continuity Test tab 1120 (FIG. 11) reveals the display shown in FIG. 12. The Continuity Test tab allows the user to test for an uninterrupted connection/continuation between components. As shown in FIG. 12, Continuity Test tab 1120 is comprised of four input windows: Stimulus Current Value window 1210, Resistance Less Than window 1220, Maximum Dwell Time window 1230, and Minimum Dwell Time window 1240. The Stimulus Current Value window 1210 allows the user to enter the current value to be tested. Text located above window 1210 provides the user with the acceptable input range. Once the stimulus value has been entered, a resistance range associated with the stimulus value will be displayed below window 1210, and the user will be given an opportunity to input a value in the Resistance Less Than window 1220. This resistance value will determine the pass/fail condition of a test. The user may next input a value in the Maximum Dwell Time window 1230. Maximum Dwell Time is the total amount of time the system applies a stimulus. The user may then input a value in the Minimum Dwell Time window 1240. Minimum dwell time is the period the system applies a stimulus before a measurement is made. When high voltages are involved, minimum dwell is necessary to ensure that the product is fully charged before measurement begins.

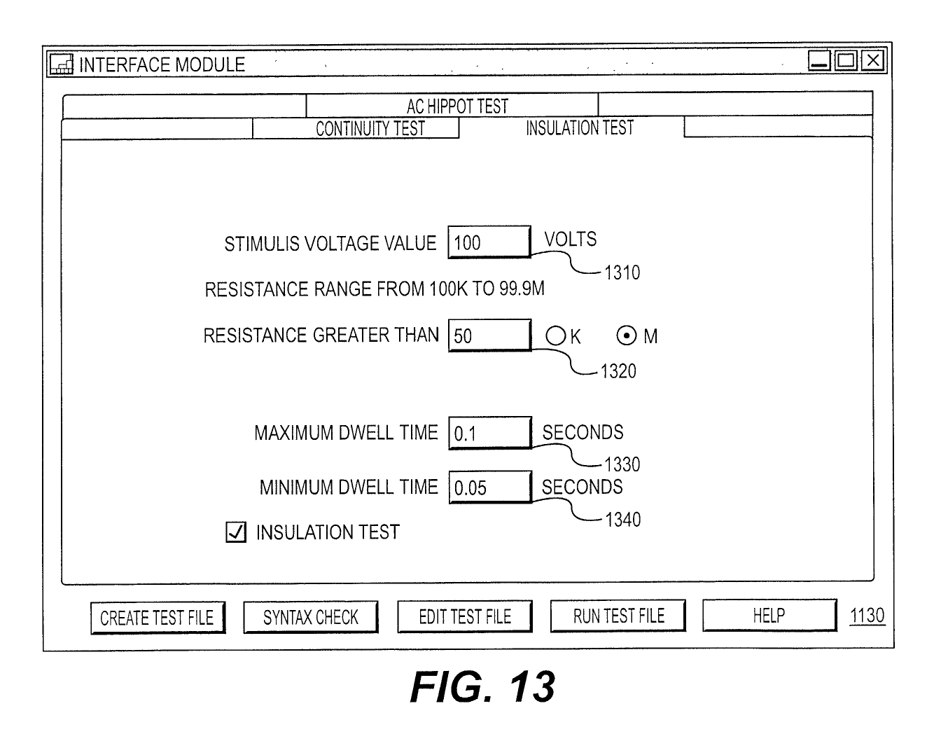

Clicking on the Insulation Test tab 1130 (FIG. 11) causes the display shown in FIG. 13 to appear. The Insulation test will attempt to identify improper shorts between wires. When enabled, this test mode will perform a lower order bulk test for the lowest address pin of each circuit string, testing the pin against all lower test addresses. As shown in FIG. 13, Insulation Test tab comprises four input windows: Stimulus Voltage Value window 1310, Resistance Greater Than window 1320, Maximum Dwell Time window 1330, and Minimum Dwell Time window 1340. The Stimulus Voltage Value window 1310 allows the user to enter the current voltage value to be tested. Text located above window 1310 provides the user with the acceptable input range. Once the stimulus voltage value has been entered, a resistance range associated with the stimulus value will be displayed below window 1310, and the user will be given an opportunity to input a value in the Resistance Greater Than window 1320. This resistance value will determine the pass/fail condition of a test. The user may next input a value in the Maximum Dwell Time window 1330. Maximum Dwell Time is the total amount of time the system applies a stimulus. The user may then input a value in the Minimum Dwell Time window 1340. Minimum dwell time is the period the system applies a stimulus before a measurement is made. When high voltages are involved, minimum dwell is necessary to ensure that the product is fully charged before measurement begins.

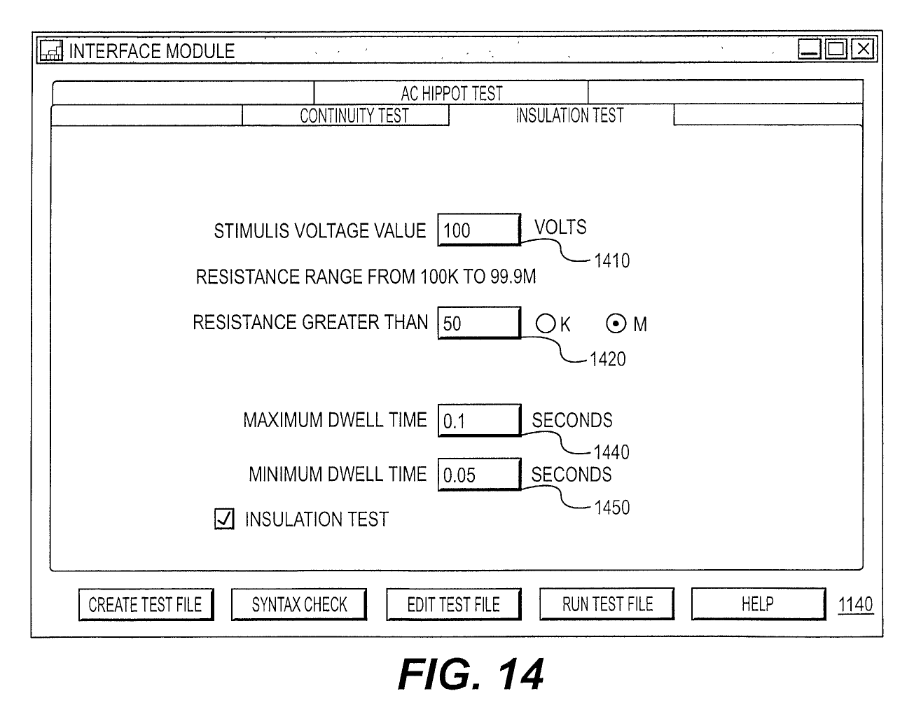

Clicking on the Isolation Test tab 1140 (FIG. 11) reveals the display shown in FIG. 14. The Isolation test attempts to identify whether a spare pin has shorted to any other point, including ground. When the Isolation Test is selected, an all-points bulk test is performed for each spare pin, testing it against all other test addresses. As shown in FIG. 14, Isolation Test tab comprises four input windows: Stimulus Voltage Value window 1410, Resistance Greater Than window 1420, Maximum Dwell Time window 1430, and Minimum Dwell Time window 1440. These windows are identical to the windows described with respect to FIG. 13. For the sake of brevity they will not be explained again here.

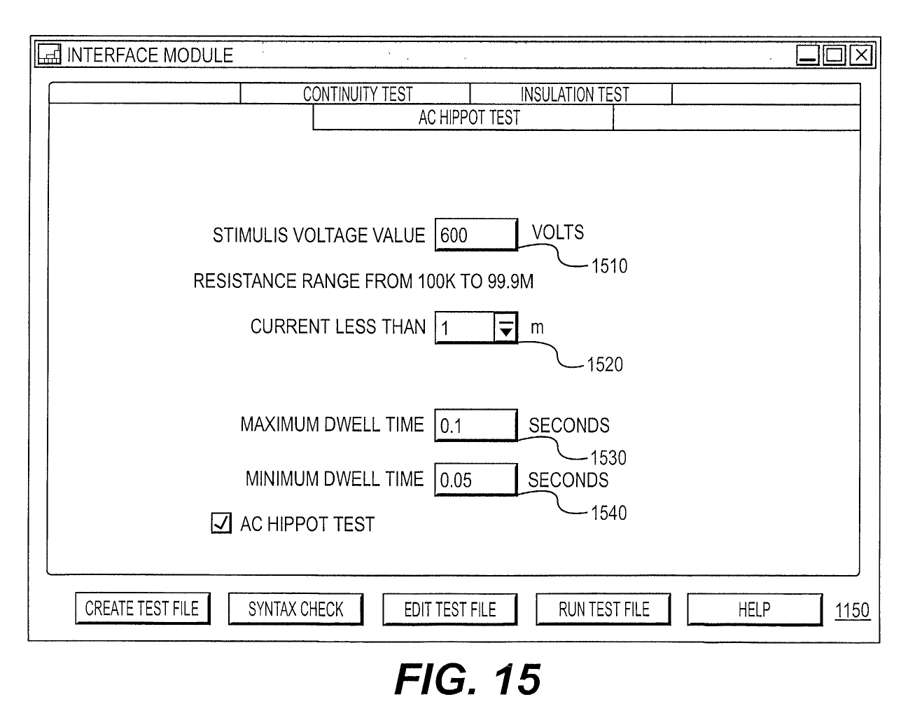

Clicking on DC HiPot Test tab 1150 (FIG. 11) reveals the display shown in FIG. 15. The DC HiPot Test is similar to the Insulation Test, described above, except that a higher stimulus is applied and a failure occurs when the current exceeds the specified limit, indicating a breakdown in UUT 126. As shown in FIG. 15, DC HiPot Test tab 1150 comprises four input windows: Stimulus Voltage Value window 1510, Current Less Than window 1520, Maximum Dwell Time window 1530, and Minimum Dwell Time window 1540. The Stimulus Current Value window 1510 allows the user to enter a stimulus value within the range to be tested. Text located above window 1510 provides the user with the acceptable input range. The user is next given the opportunity to select a value for Current Less Than window 1520 from a drop-down menu. This resistance value will determine the pass/fail condition of a test. The user may next input a value in the Maximum Dwell Time window 1530 and the Minimum Dwell Time window 1540. These values are identical to the similarly named values listed above.

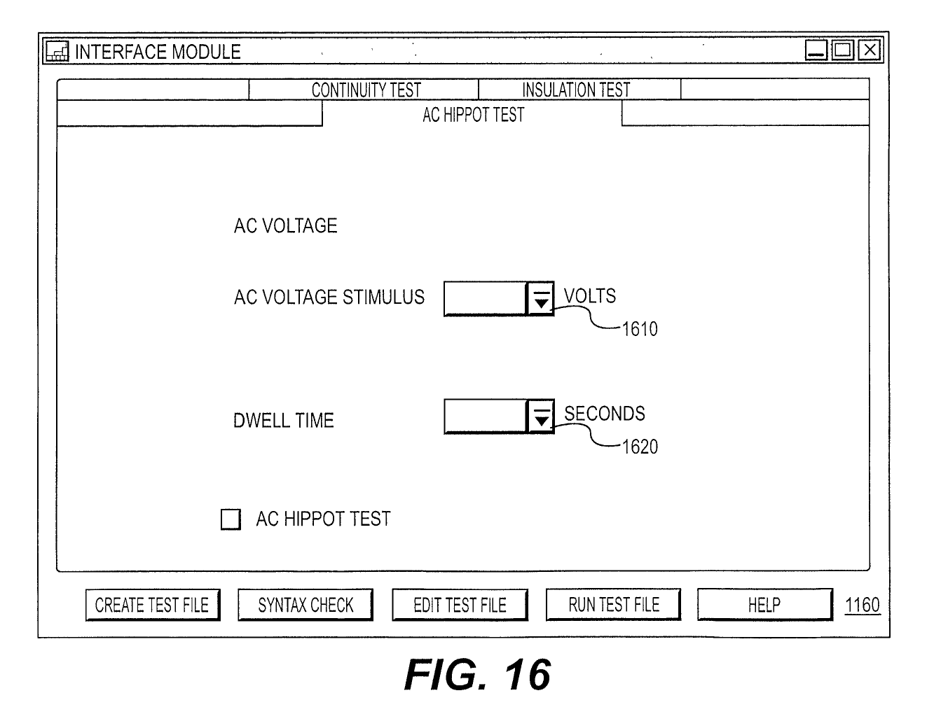

Clicking on AC HiPot tab 1160 (FIG. 11) reveals the display shown in FIG. 16. The AC HiPot Test is similar to the DC HiPot test, except that a higher stimulus range is typically used. As shown in FIG. 16, AC HiPot Test tab 1160 contains two windows: AC Voltage Stimulus 1610 and Dwell Time 1620. A user may enter a value in AC Voltage Stimulus window 1610 from a drop down menu. As shown in FIG. 16, the user may be prompted with a message above window 1610 that gives the user an indication of the acceptable range of inputs for the AC Voltage Stimulus. The user may next input a maximum Dwell Time 1620 from the drop down menu. In one embodiment, an acceptable range is between 1 and 9 seconds, depending on the application.

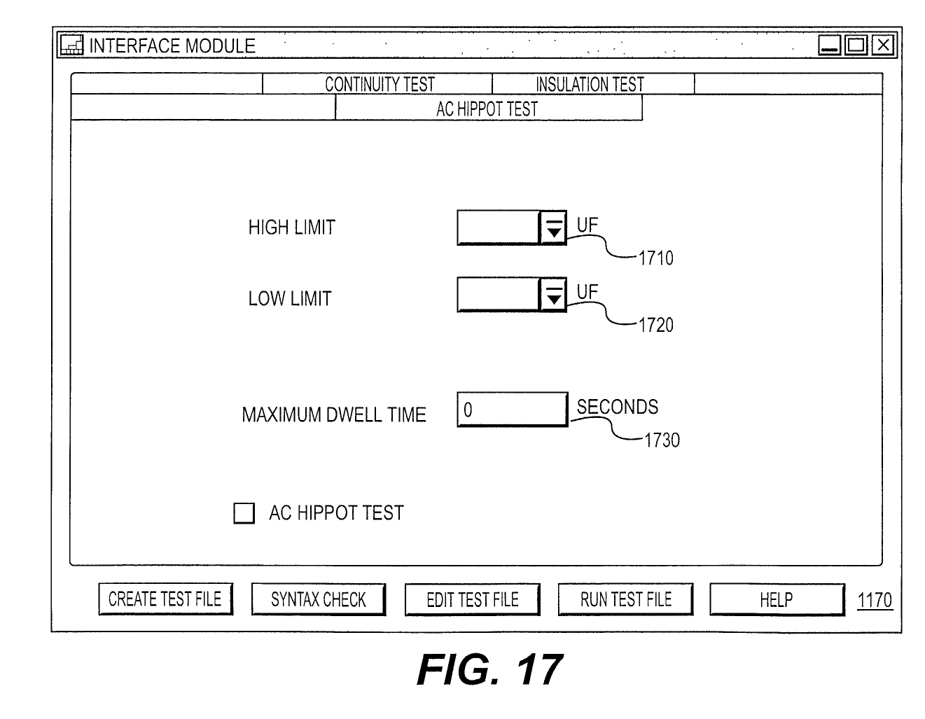

Clicking on the Capacitance Test tab 1170 (FIG. 11) reveals the display shown in FIG. 17. The Capacitance Test is similar to the Insulation Test (described above), except that it tests capacitance instead of resistance. As shown in FIG. 17, the Capacitance Test tab contains three windows: High Limit 1710, Low Limit 1720, and Maximum Dwell Time 1730. High Limit 1710 is a pull down list containing a set of capacitance values ranging from 0.1 to 100. Low Limit 1720 is a pull down list containing a set of capacitance values ranging from 1 to 100. Maximum Dwell Time 1730 is the total amount of time the system applies a stimulus.

After selecting and completing the appropriate tabs, the user could then select one or more of the following: Create Test File button 1180, Syntax Check button 1190, Edit Test File button 1192, Run Test File button 1194, and a Help button 1196 (shown in FIG. 11.) In operation, the user would normally select Create Test File button 1180 to create a test from the previous inputs. If a test has already been created, the user would then select Syntax Check button 1190 to check the syntax of an existing test. In the event the user seeks to edit a test, he/she would select Edit Test File button 1192. Once the inputting, checking, and editing are completed, the user would select Run Test File button 1194 to run the test.

From the foregoing description, it will be appreciated that the present invention provides an efficient system and method analyzing the overall performance of a wiring architecture. The present invention has been described in relation to particular embodiments which are intended in all respects to be illustrative rather than restrictive. Those skilled in the art will appreciate that many different combinations of hardware will be suitable for practicing the present invention. Many commercially available substitutes, each having somewhat different cost and performance characteristics, exist for each of the components described above.

Although aspects of the present invention are described as being stored in memory, one skilled in the art will appreciate that these aspects can also be stored on or read from other types of computer-readable media, such as secondary storage devices, like hard disks, floppy disks, or CD-ROMs; a carrier wave from the Internet; or other forms of RAM or ROM. Similarly, the method of the present invention may conveniently be implemented in program modules that are based upon the flow chart in FIG. 23. No particular programming language has been indicated for carrying out the various procedures described above because it is considered that the operations, steps and procedures described above and illustrated in the accompanying drawings are sufficiently disclosed to permit one of ordinary skill in the art to practice the instant invention. Moreover, there are many computers and operating systems which may be used in practicing the instant invention and therefore no detailed computer program could be provided which would be applicable to these many different systems. Each user of a particular computer will be aware of the language and tools which are most useful for that user's needs and purposes.

Alternative embodiments will become apparent to those skilled in the art to which the present invention pertains without departing from its spirit and scope. Accordingly, the scope of the present invention is defined by the appended claims rather than the foregoing description.

What is claimed is:

1. An apparatus for testing a unit under test (UUT) comprising an automatic test equipment (ATE) controller adapted to be connected to the UUT, said ATE controller comprising:
a processor; and
a memory coupled to the processor for storing:
a plurality of component records representing a plurality of objects each having a predetermined function; and
at least one channel record representing a predetermined interface between at least two component records;
a database of a plurality test program segments;
an automatic test generator for creating a test program from said test program segments, said test program segments are selected based on user inputs; and
an ATE processing system for executing a test program and storing results in a testing results data file comprising data indicating the results obtained by comparing the results observed during a test of the UUT with expected results stored in said plurality of component records.

2. The apparatus of claim 1, wherein said predetermined interface is a power, data, optical, hydraulic, or thermal interface.

3. The apparatus of claim 2, wherein said memory further comprises a wire node information file comprised of expected data values for each power interface.

4. The apparatus of claim 1, wherein said memory further comprises a graphical display routine for automatically generating a wiring diagram from said plurality of component records and channel records.

5. In a system comprising an automatic test equipment (ATE) controller, a method of testing a unit under test (UUT), wherein said ATE controller comprises a processor and a memory that further comprises: a plurality of component records representing a plurality of objects each having a predetermined function; at least one channel record representing a predetermined interface between at least two component records; a database of a plurality test program segments; and an automatic test program generator (ATG), said method comprising the steps of:
connecting the UUT to said ATE controller;
causing said ATE controller to execute the ATG software, such that a testing program is generated, said test program comprising a plurality of test program segments automatically selected based on user inputs to said ATG software;
executing the test program to produce a testing results data file; and
evaluating the testing results data file to identify defective components and interfaces; said defects being identified by comparing results observed during a test of the UUT with expected results stored in said plurality of component records.

6. In a system comprising a plurality of automatic test equipment (ATE) controllers coupled together on a network, a method of testing a unit under test (UUT), wherein each of said plurality of ATE controllers comprises a processor and a memory that further comprises: a plurality of component records representing a plurality of objects each having a predetermined function; at least one channel record representing a predetermined interface between at least two component records; a database of a plurality test program segments; and an automatic test program generator (ATG), said method comprising the steps of:
connecting the UUT to one of the plurality of ATE controllers;
causing said ATE controller to execute the ATG software, such that a testing program is generated, said test program comprising a plurality of test program segments automatically selected based on user inputs to said ATG software;
executing the test program to produce a testing results data file; and
evaluating the testing results data file to identify defective components and interfaces; said defects being identified by comparing results observed during a test of the UUT with expected results stored in said plurality of component records.

7. The method of claim 6, further comprising the step of determining expected values by accessing historical performance data from said plurality of ATE controllers.

8. The method of claim 7, wherein said defects are identified by comparing results observed during a test with expected results stored in component records associated with said plurality of component records.
